(19) United States
(12) Patent Application Publication
(10) Pub. No.: US 2008/0267060 A1
(43) Pub. Date: Oct. 30, 2008

(54) METHOD, SYSTEM AND COMPUTER PROGRAM PRODUCT FOR PROVIDING HIGH SPEED FAULT TRACING WITHIN A BLADE CENTER SYSTEM

(75) Inventors: Katherine T. Blinick, Tucson, AZ (US); Gregg S. Lucas, Tucson, AZ (US); Robert E. Medlin, Tucson, AZ (US); Gordon L. Washburn, Tucson, AZ (US)

Correspondence Address: CANTOR COLBURN LLP - IBM TUSCON DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/740,628

(22) Filed: Apr. 26, 2007

(51) Int. Cl. G01R 31/08

(52) U.S. Cl. 370/216

(57) ABSTRACT

Providing high speed fault tracing within a blade center system by using a high speed transmitter port of a switch to implement a first snoop port and using a high speed receiver port of the switch to implement a second snoop port, thus permitting snooping of the blade center system from a single blade slot.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

The present invention relates generally to data processing systems and, more specifically, to a method, system, and computer program product for providing high speed fault tracing within a blade center system.

2. Description of Background

A blade center is a server chassis housing multiple thin, modular electronic circuit boards known as server blades. Each server blade is a server containing a processor, memory, integrated network controllers, and input/output (I/O) ports. Blade centers allow more processing power in less rack space, simplifying cabling and reducing power consumption. Each blade typically includes one or two local Advanced Technology Attachment (ATA) or Small Computer System Interface (SCSI) drives. For additional storage, blade servers can connect to a storage pool facilitated by network-attached storage (NAS), fiber channel, or Internet SCSI (i-SCSI).

A blade center system includes a plurality of server blades, dual switch modules, and an internal or external storage mechanism. These dual switch modules are used to provide connectivity among the plurality of server blades, and also to provide connectivity between the server blades and the storage mechanism. These switches may, but need not, be implemented using serial-attached SCSI (SAS) switches. Blade center systems are intended to simplify matters for customers by internalizing as much of a storage area network (SAN) as is feasible, thereby providing a “store-in-a-box” type of solution. With such high levels of integration, much of the network becomes internalized.

As a practical matter, storage systems may experience problems or malfunctions from time to time. In order to resolve these problems and malfunctions, it may be necessary to access pertinent data from the storage system. In open-style SAN networks, it is easy to insert or attach test equipment, such as a logic analyzer, onto a suspected high-speed interface, such as fiber channel, so as to capture pertinent data for problem resolution. On the other hand, due to the fact that the high speed switching fabric of a blade center system is internalized, it becomes difficult to access the fabric for the purpose of troubleshooting problems. Many existing blade center systems provide no method to directly monitor the switching fabric. Alternate, less desirable, methods have been concocted such as creating software trace events in microcode and directing error messages to a debug port. There are many shortcomings inherent in this approach, such as acquiring inaccurate information, obtaining information that lacks sufficient detail for properly characterizing a failure, non real time reporting of a failure, and undergoing multiple iterations of debug patches to arrive at the root cause of a problem.

Other, more invasive, methods may be employed to troubleshoot a blade center system, such as adding wires to a circuit board card to permit internal probing. This hardware-style approach is severely invasive and limiting, causing potential corruption of the data being monitored or, even worse, causing permanent electrical damage to the probed switching fabric circuitry. At best, this approach is relegated to development laboratory environments where the intricacies of such probing can be managed and monitored.

In view of the foregoing considerations, there is no known effective method to troubleshoot internalized high speed switching fabric networks such as those found in blade center systems. Moreover, there is no known effective method for internally tracing or “snooping” server blade traffic without using external switch ports. For example, some current snoop implementations are able to provide a single snoop port per SAS switch by using an available high speed transmitter port of the switch. If a plurality of snoop ports are required to troubleshoot a problem, it will be necessary to utilize the transmitter ports on a plurality of blade slots. However, some external switch ports may be actively connected to external storage, thus not permitting the port to be attached to a logic analyzer or other test equipment. Accordingly, what is needed is a technique for providing internal tracing or “snooping” of selective internalized high speed interfaces within a blade center system.

### SUMMARY OF THE INVENTION

The shortcomings of the prior art are overcome and additional advantages are provided by using a high speed transmitter port of a switch to implement a first snoop port and using a high speed receiver port of the switch to implement a second snoop port, thus permitting snooping of a blade center system from a single blade slot.

Systems and computer programs product corresponding to the above-summarized methods are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution wherein a single blade slot of a blade center system is utilized to provide two snoop ports, thereby doubling the number of snoop ports that may be implemented on a blade slot relative to existing techniques.

### BRIEF DESCRIPTION OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a related art blade center system utilizing external storage.

FIG. 2 illustrates a related art blade center system utilizing internal storage.

FIG. 3 illustrates a related art blade center system that uses a switch module to provide a snoop port and would require a plurality of blade slots to provide a plurality of snoop ports.

FIG. 4 illustrates an exemplary blade center system that uses a switch module to provide a plurality of snoop ports.

FIG. 5 shows an illustrative method for using the blade center system of FIG. 4 to capture a failure event.

Like reference numerals are used to refer to like elements throughout the drawings. The detailed description explains the preferred embodiments of the invention, together with advantages and features, by way of example with reference to the drawings.

### DETAILED DESCRIPTION OF THE INVENTION

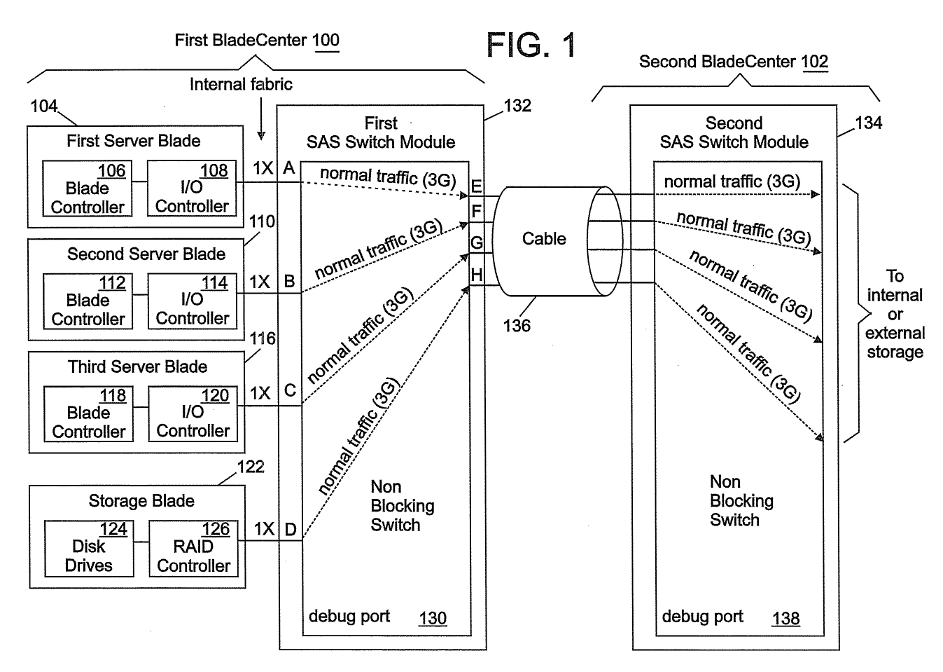

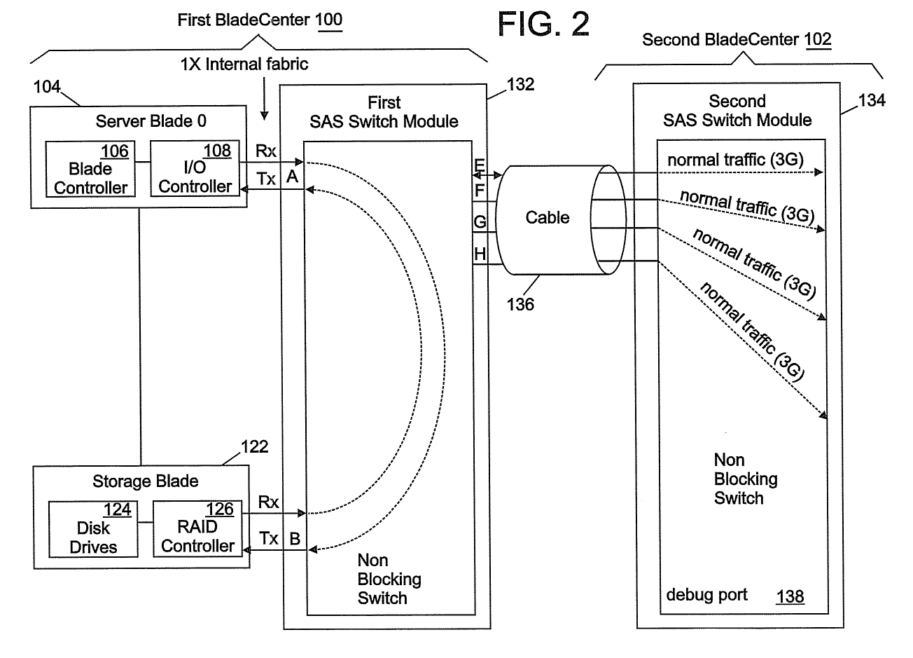

Recent advances in high speed switch technology provide the ability to selectively and redundantly mirror high speed traffic to other ports on the same switch. This feature is also known as “snooping”, in the sense that high speed traffic in progress between two switch ports can be “snooped” or monitored and then directed to yet another port on a switch dedicated for snooping. There are two storage configurations to consider for snooping: FIG. 1 illustrates a related art blade center system utilizing external storage, whereas FIG. 2 illustrates a related art blade center system utilizing internal storage. However, it should be understood that some blade center systems may utilize a combination of internal as well as external storage.

Referring to FIG. 1, a blade center system includes a first blade center 100 and a second blade center 102. First blade center 100 includes a first serial-attached SCSI (SAS) switch module 132 operatively coupled to a plurality of server blades including a first server blade 104, a second server blade 110, and a third server blade 116. First server blade 104 includes a blade controller 106 and an I/O controller 108, each illustratively implemented using one or more microprocessor-based devices. Likewise, second server blade 110 includes a blade controller 112 and an I/O controller 114, and third server blade 116 includes a blade controller 118 and an I/O controller 120. A storage blade 122, providing storage for first blade center 100, includes one or more disk drives 124 and a redundant array of inexpensive disks (RAID) controller 126.

Second blade center 102, including a second SAS switch module 134, may be connected to one or more internal or external storage devices (not shown). First SAS switch module 132 is operatively coupled to second SAS switch module 134 through a cable 136. First and second SAS switch modules 132, 134 are non-blocking switches. First SAS switch module 132 includes a debug port 130 for accessing information to aid in troubleshooting and fault detection. This is a useful feature because interconnections between first SAS switch module 132 and each of the blade servers 104, 110, 116 are provided over an internal switching fabric that is difficult or impossible to access once initial installation is complete. Similarly, second SAS switch module 134 also includes a debug port 138.

Referring to FIG. 2, a blade center system utilizing internal storage includes a first blade center 100 and a second blade center 102. First blade center 100 includes a first serial-attached SCSI (SAS) switch module 132 operatively coupled to a server blade 104 and a storage blade 122. First server blade 104 includes a blade controller 106 and an I/O controller 108, each illustratively implemented using one or more microprocessor-based devices. Storage blade 122, providing storage for first blade center 100, includes one or more disk drives 124 and a RAID controller 126.

Second blade center 102 includes a second SAS switch module 134. First SAS switch module 132 is operatively coupled to second SAS switch module 134 through a cable 136. First and second SAS switch modules 132, 134 are non-blocking switches. First SAS switch module 132 includes a first switch port A operatively coupled to server blade 104, and a second switch port B operatively coupled to storage blade 122. First switch port A and second switch port B each represent a differential transmitter/receiver port pair. In some situations, there are no available switch ports on first SAS switch module 132 for use as debug port for accessing information to aid in troubleshooting and fault detection. Second SAS switch module includes a debug port 138.

When troubleshooting system I/O problems amongst server blades 104, 110, 116 and storage blade 122 (FIGS. 1 and 2), it becomes necessary to capture a trace of I/O activity in real time. In many cases, it is impractical to direct internal trace data to external switch ports. For example, all external switch ports may be dedicated to external storage applications. Thus it is necessary to provide an internalized trace or “snooping” function. Data acquired by this snooping function can be directed to an internal snoop blade that is specifically designed for capturing and externalizing trace data.

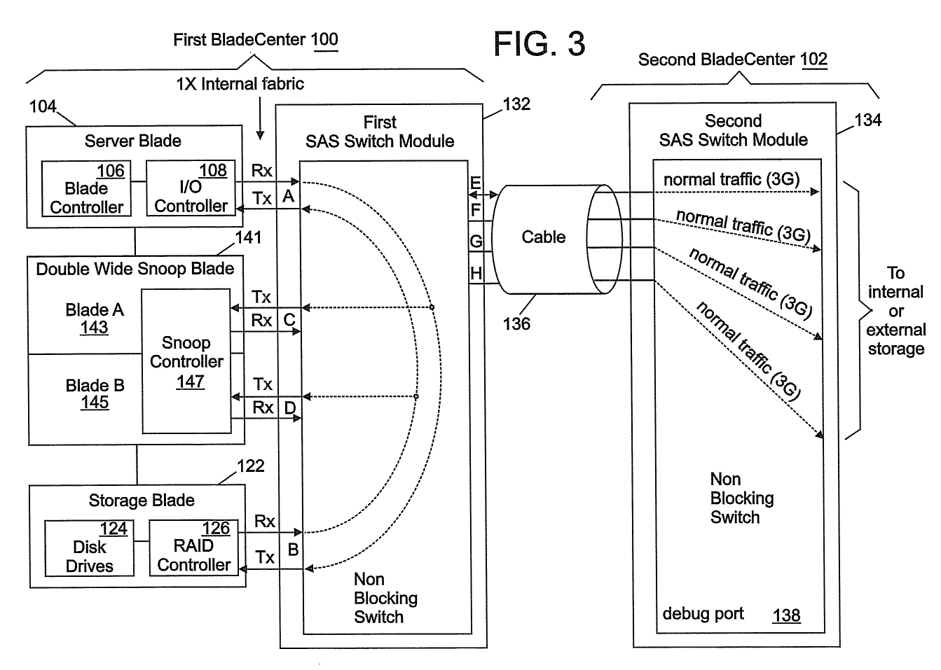

With reference to FIG. 3, one approach for providing snoop ports within an SAS switch module (such as first SAS switch module 132) is to route snoop data from a selectable switch input/output port to a selectable output port. SAS switch module 132 includes a first switch port A, a second switch port B, a third switch port C, and a fourth switch port D where each of these switch ports represents a differential transmitter/receiver port pair having a transmit port (Tx) and a receive port (Rx). More specifically, one snoop path is routed to a single transmit port (Tx) of a differential transmitter/receiver port pair. Thus, for each path port to be snooped, an entire switch port having a differential transmitter/receiver port pair must be consumed, even though only the transmit (Tx) portion of the switch port is being used. Accordingly, if third switch port C and fourth switch port D are used to implement a snoop path, only the transmit ports (Tx) of third switch port C and fourth switch port D are utilized, with the receive ports (Rx) of third switch port C and fourth switch port D remaining unused.

In general, it is not helpful to snoop just a single switch port for purposes of fault tracing. Most oftentimes, two or more switch ports, such as third switch port C and fourth switch port D, must be used to snoop to compare data into and out of server blade 104 or first SAS switch module 132. Given this requirement, a single snoop blade cannot provide adequate high speed tracing of a failing I/O traffic data stream. Accordingly, a double wide snoop blade 141 is used for fault tracing. Double wide snoop blade 141, connected to two switch ports such as third switch port C and fourth switch port D, includes two blades denoted as blade A 143 and blade B 145. Double wide snoop blade 141 also includes a snoop controller 147 implemented, for example, using a microprocessor.

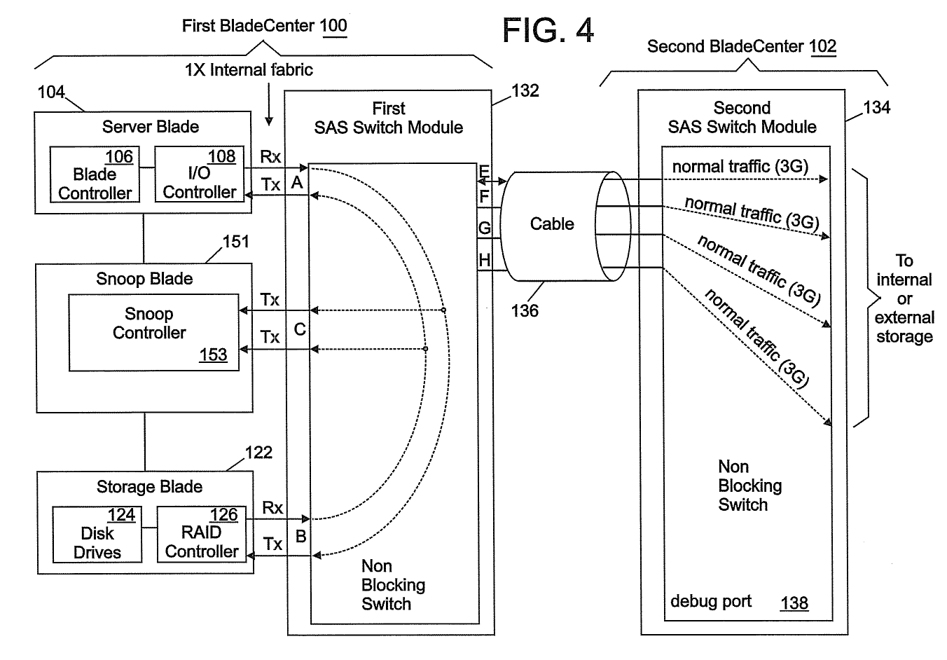

Since double wide snoop blade 141 occupies two switch ports, it would be desirable to develop a technique for replacing the double wide snoop blade with a single snoop blade that occupies only a single switch port. A solution to this dilemma, shown in FIG. 4, illustrates an exemplary blade center system that uses a switch module to provide a plurality of snoop ports. This functionality is accomplished by configuring a first SAS switch module 133 to implement one or more of its differential switch ports, such as third switch port C, to have a transmit port (Tx) that provides transmit functionality for transmitting data while, at the same time, providing a receive port (Rx) that can be selectively controlled to provide receive functionality or transmit functionality as desired. In normal operation where troubleshooting is not to be performed, the receive port (Rx) of third switch port C is controlled to provide receive functionality for receiving data. When a port, such as third switch port C, is to be configured for snooping, its receive port (Rx) is controlled to provide transmit functionality.

The implementation of FIG. 4 is advantageous in that a single switch port, such as third switch port C, can be used to provide double the snooping density relative to the configuration of FIG. 3. With double the snooping density, it is now practical to route dual snoop paths (i.e., input and output traffic) to a single blade slot. Moreover, as a practical consideration, a single blade slot is generally available in a blade center system, whereas two adjacent blade slots (as required by the configuration of FIG. 3) may be difficult to locate.

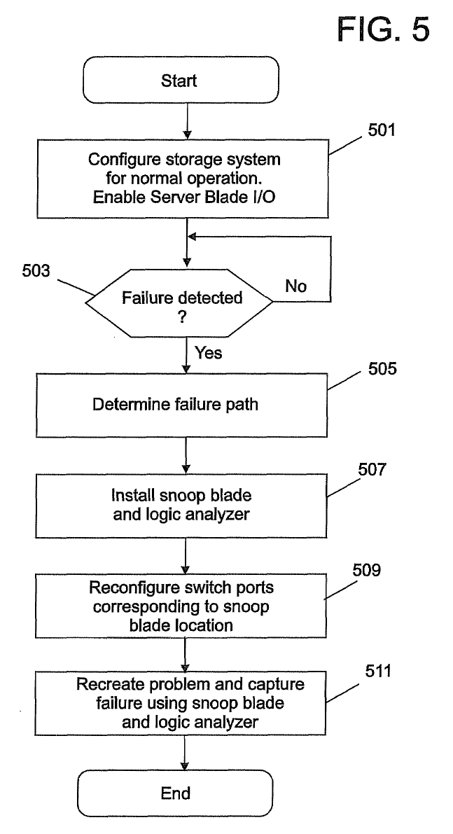

FIG. 5 shows an illustrative method for using the blade center system of FIG. 4 to capture a failure event. The procedure commences at block 501 (FIG. 5) where a storage system of a blade center (such as first blade center 100, FIG. 4) is configured for normal operation, and I/O controller 108 enables I/O for server blade 104. Next, at block 503 (FIG. 5), a test is performed to ascertain whether or not a failure has been detected. If not, the program continues ascertaining whether or not a failure has been detected. Once a failure has been detected, the failure path is determined (block 505). A snoop blade and a logic analyzer are installed (block 507). The switch port (or ports) corresponding to snoop blade location(s) are reconfigured such that the receive ports (Rx) of the switch port (or ports) is/are controlled to provide transmit functionality for transmitting data (block 509). The problem is recreated and failure data is captured using the installed snoop blade and logic analyzer (block 511).

The capabilities of the present invention can be implemented in software, firmware, hardware or some combination thereof. As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for providing fault tracing within a blade center system that includes a plurality of blade slots and a switch having a differential switch port comprising a transmit port and a receive port, the method comprising:
using the transmit port to implement a first snoop port; and
using the receive port to implement a second snoop port by selectively controlling the receive port to implement a transmit functionality for transmitting data, wherein the first and second snoop ports are provided within a single blade slot, thus permitting snooping of the blade center system from a single blade slot.

2. The method of claim 1 further comprising using the first and second snoop ports to perform fault tracing.

3. The method of claim 2 further comprising selectively controlling the receive port to implement a receive functionality for receiving data upon completion of the fault tracing.

4. A computer program product for providing fault tracing within a blade center system that includes a plurality of blade slots and a switch having a differential switch port comprising a transmit port and a receive port, the computer program product comprising a storage medium readable by a processing circuit and storing instructions for execution by the processing circuit for facilitating a method comprising:
using the transmit port to implement a first snoop port; and
using the receive port to implement a second snoop port by selectively controlling the receive port to implement a transmit functionality for transmitting data, wherein the first and second snoop ports are provided within a single blade slot, thus permitting snooping of the blade center system from a single blade slot.

5. The computer program product of claim 4 further comprising instructions for using the first and second snoop ports to perform fault tracing.

6. The computer program product of claim 5 further comprising instructions for selectively controlling the receive port to implement a receive functionality for receiving data upon completion of the fault tracing.

7. A blade center system including:
a plurality of blade slots each configured to accept a server blade;
a switch operatively coupled to the plurality of blade slots, the switch having a differential switch port comprising a transmit port and a receive port, wherein the transmit port is used to implement a first snoop port, and the receive port is used to implement a second snoop port by the switch selectively controlling the receive port to implement a transmit functionality for transmitting data, such that the first and second snoop ports are provided within a single blade slot of the plurality of blade slots.

8. The blade center system of claim 7 further comprising a fault tracing mechanism capable of using the first and second snoop ports to perform fault tracing.

9. The blade center system of claim 7 wherein the fault tracing mechanism comprises a logic analyzer.

10. The blade center system of claim 7 wherein the switch is capable of selectively controlling the receive port to implement a receive functionality for receiving data upon completion of the fault tracing.
